(19) United States
(12) Patent Application Publication
(10) Pub. No.: US 2020/0243551 A1
(43) Pub. Date: Jul. 30, 2020

(54) NON-VOLATILE MEMORY AND MANUFACTURING METHOD FOR THE SAME

(71) Applicant: Nexchip Semiconductor Co., LTD., Hefei (CN)

(72) Inventor: Geeng-Chuan CHERN, Hefei (CN)

(73) Assignee: Nexchip Semiconductor Co., LTD., Hefei (CN)

(21) Appl. No.: 16/368,889

(22) Filed: Mar. 29, 2019

(30) Foreign Application Priority Data
Jan. 25, 2019 (CN) 2019100732638

(51) Int. Cl. H01L 27/11521; H01L 29/788; H01L 29/08; H01L 29/10; H01L 29/45; H01L 29/66; H01L 21/28; H01L 21/266; H01L 21/265; H01L 29/423; G11C 16/10; G11C 16/14; G11C 16/26; G11C 16/04

(52) U.S. Cl. CPC H01L 27/11521; H01L 21/02164; H01L 29/0847; H01L 29/1033; H01L 29/45; H01L 29/66825; H01L 21/28273; H01L 21/266; H01L 21/26513; H01L 29/42324; G11C 16/10; G11C 16/14; G11C 16/26; G11C 16/0408; H01L 29/788

(57) ABSTRACT

The present disclosure provides a non-volatile memory and a manufacturing method for the same, including: a substrate; a floating gate structure located on the substrate, the floating gate structure sequentially includes a floating gate dielectric layer and a floating gate conductive layer; a word line structure located on the floating gate structure, the word line structure sequentially includes a word line dielectric layer and a word line conductive layer; a drain region located on the substrate, the drain region is adjacent to a first edge of the floating gate structure; a source region located on the substrate, the source region is adjacent to a second edge of the floating gate structure; a peripheral doped region located on the substrate, the peripheral doped region is formed around both sides of the source region and is adjacent to the second edge of the floating gate structure.

### CROSS REFERENCES TO RELATED APPLICATIONS

This application claims the benefits of priority to a Chinese Patent Application No. CN 2019100732638 filed on Jan. 25, 2019, entitled “Non-Volatile Memory and Manufacturing Method for the same”, and the contents of which are incorporated herein by reference in its entirety.

### BACKGROUND OF THE PRESENT DISCLOSURE

### Field of Disclosure

The present disclosure relates to the field of semiconductors, and in particular to a non-volatile memory and a manufacturing method for the same.

### Description of Related Arts

In a non-volatile memory, operations such as data storage, reading, and erasing can be performed for many times, and stored data does not disappear after power-off. Therefore, the non-volatile memory is widely applied in personal computers, electronic devices, and the like.

The non-volatile memory typically uses a Stack-Gate structure. In the Stack-Gate structure, programming, erasing, and reading of the non-volatile memory are usually based on multiple mechanisms. It is known that a mechanism of programming through band-to-band tunneling induced substrate hot electron injection and reading through a gate induced drain leakage current is disclosed in the prior art. The programming mechanism can reduce a programming current. However, a source region and a drain region are formed by using a non-self-aligned process before a gate is formed. Especially, when the source and drain regions are formed by using different types of doping in different mask steps, the size of a memory cell is increased due to mis-alignment tolerance. Moreover, when reading is performed through a gate induced drain leakage current mechanism, a negative word line voltage is required in the reading process. Therefore, the circuit design for a reading operation is more complex.

At present, integrated circuits are developed to be miniaturized elements with a higher degree of integration. Therefore, the size of the memory cell of the non-volatile memory needs to be reduced to improve the degree of integration thereof.

### SUMMARY OF THE PRESENT DISCLOSURE

In view of the foregoing disadvantages of the prior art, the present application provides a non-volatile memory and a manufacturing method for the same, and is specifically about a non-volatile memory having a tunneling field effect transistor structure.

The present disclosure provides a non-volatile memory, including: a substrate; at least one floating gate structure located on the substrate, the floating gate structure sequentially includes a floating gate dielectric layer and a floating gate conductive layer; at least one word line structure located on the floating gate structure, the word line structure sequentially includes a word line dielectric layer and a word line conductive layer; at least one drain region located on the substrate, the drain region is adjacent to a first edge of the floating gate structure; at least one source region located on the substrate, the source region is adjacent to a second edge of the floating gate structure; and at least one peripheral doped region located in the substrate, the peripheral doped region is formed around both sides of the source region and is adjacent to the second edge of the floating gate structure.

The floating gate dielectric layer is located on the substrate, and the floating gate conductive layer has a thickness ranging from 7 to 14 nm.

The floating gate conductive layer is located on the floating gate dielectric layer, and the floating gate conductive layer has a thickness ranging from 8 to 50 nm.

The word line dielectric layer is located on the floating gate conductive layer; and the word line conductive layer is located on the word line dielectric layer.

The floating gate structure is located between the drain region and the source region.

A doping type of the drain region is different from a doping type of the source region. First doping is used for the drain region, and the first doping includes N-type doping. Second doping is used for the source region, and the second doping includes P-type doping.

A doping type of the peripheral doped region is different from the doping type of the source region.

The doping type of the peripheral doped region is the same as the doping type of the drain region.

A thickness of the peripheral doped region is less than a thickness of the source region. The peripheral doped region is located under the floating gate structure.

The memory may further include self-aligned silicide layers, the self-aligned silicide layers are located on the word line structure, the drain region and the source region.

The memory may further include an inter-layer dielectric layer, at least one bit line, and at least one contact plug. The inter-layer dielectric layer is located on the substrate and covers the floating gate structure and the word line structure. The contact plug is located in the inter-layer dielectric layer. A top end of the contact plug is connected to the bit line, and a bottom end of the contact plug is connected to the drain region.

The memory further comprises sidewall structures, the sidewall structures is located at both sides of the word line structure and the floating gate structure.

When a voltage is applied on the word line structure, an inversion channel is formed under the floating gate structure, the drain region and the peripheral doped region are connected through the inversion channel.

When a voltage is applied on the word line structure, a band-to-band tunnel may be formed between the source region and the peripheral doped region.

The present disclosure further provides a manufacturing method for a non-volatile memory, which at least includes: providing a substrate; forming at least one floating gate structure on the substrate, the floating gate structure sequentially includes a floating gate dielectric layer and a floating gate conductive layer; forming at least one word line structure on the floating gate structure, the word line structure sequentially includes a word line dielectric layer and a word line conductive layer; forming at least one drain region on the substrate, the drain region is adjacent to a first edge of the floating gate structure; forming at least one source region on the substrate, the source region is adjacent to a second edge of the floating gate structure; and forming at least one peripheral doped region in the substrate, the peripheral doped region is located around both sides of the source region and is adjacent to the second edge of the floating gate structure.

Forming the floating gate structure at least includes: forming a first gate dielectric layer on the substrate, the first gate dielectric layer includes an oxide and a nitrogen oxide, and the thickness of the first gate dielectric layer ranges from 7 to 14 nm; forming a first conductive layer on the first gate dielectric layer, the first conductive layer includes P-type or N-type polysilicon, and the thickness of the first conductive layer ranges from 8 to 50 nm; and removing a part of the first gate dielectric layer and a part of the first conductive layer, to form the floating gate structure extending along a first direction.

Forming the word line structure at least includes: forming a second gate dielectric layer on the floating gate structure and the exposed first gate dielectric layer, the second gate dielectric layer includes an oxide, or a nitride, or a combination of an oxide and a nitride, the thickness of the oxide ranges from 3 to 7 nm, and the thickness of the nitride ranges from 4 to 8 nm; forming a second conductive layer on the second gate dielectric layer, the second conductive layer includes N-type polysilicon, and the thickness of the second conductive layer ranges from 80 to 250 nm; and removing a part of the second conductive layer, a part of the second gate dielectric layer, a part of the first conductive layer, and a part of the first gate dielectric layer, to form the word line structure, where the first gate dielectric layer is wet-etched during removal of the first gate dielectric layer.

Forming the drain region at least includes: forming a patterned photoresist layer on the word line structure and the substrate surrounded by the word line structure, to expose a part of the substrate; performing first-type doping on the exposed part of the substrate to form the drain region, the first-type doping is N-type doping, and the drain region is adjacent to a first edge of the floating gate structure.

Forming the source region and the peripheral doped region at least includes: forming a patterned photoresist layer on the substrate, the patterned photoresist layer covers the drain region, to expose a part of the substrate; performing second-type doping on the exposed part of the substrate to form the source region, the second-type doping is P-type doping, and the source region is adjacent to a second edge of the floating gate structure; and performing first-type doping on the exposed part of the substrate to form the peripheral doped region, the peripheral doped region is located around both sides of the source region, and the peripheral doped region is adjacent to the second edge of the floating gate structure; during forming of the peripheral doped region, tilted implantation may be used, a tilt angle ranges from 25° to 60°, doping energy ranges from 10 to 30 KeV, and an ion implantation dosage ranges from 10¹⁴/cm² to 10¹⁵/cm².

The manufacturing method may further include: forming an inter-layer dielectric layer on the substrate, the inter-layer dielectric layer covers the floating gate structure and the word line structure; forming at least one contact plug in the inter-layer dielectric layer, a bottom end of the contact plug is connected to the drain region; and forming at least one bit line on the inter-layer dielectric layer, the bit line is connected to a top end of the contact plug.

The manufacturing method may further include: forming sidewall structures, the sidewall structures are located at both sides of the word line structure and the floating gate structure, the height of the sidewall structures is the same as the height of the word line structure.

The manufacturing method may further include: forming self-aligned silicide layers on the word line structure, the drain region, and the source region.

In conclusion, the present disclosure provides a non-volatile memory and a manufacturing method for the same. A peripheral doped region is formed on a substrate, the peripheral doped region is located around both sides of a source region; and during reading operations, an inversion channel is formed, the peripheral doped region and a drain region are connected through the inversion channel. The power supply voltage can be reduced, and the circuit design can be simplified. Moreover, the non-volatile memory provided in the present disclosure has a simple structure, a highly operable manufacturing process, and great promotional value.

### BRIEF DESCRIPTION OF THE DRAWINGS

FIG. 1 is a circuit diagram of a non-volatile memory consistent with the present disclosure.

FIG. 2 is a plane layout of the non-volatile memory consistent with the present disclosure.

FIG. 2A is a cross-section diagram taken along line A-A′ in FIG. 2.

FIG. 2B is a cross-section diagram taken along line B-B′ in FIG. 2.

FIG. 3 is a process flowchart of a manufacturing method for a non-volatile memory consistent with the present disclosure.

FIGS. 4 to 27 are schematic diagrams of cross-section structures presented in steps of the manufacturing method for a non-volatile memory consistent with the present disclosure.

FIGS. 28 to 30 are schematic diagrams of cross-section structures corresponding to programming, erasing, and reading operations of a non-volatile memory consistent with the present disclosure.

### DESCRIPTION OF REFERENCE NUMERALS

100 Memory
101 Bit line
102 Word line
103 Floating gate
104 Contact region
105 Active region
201 Substrate
202 Shallow trench isolation structure
203 First gate dielectric layer
203a Floating gate dielectric layer
204 First conductive layer
205 Patterned photoresist layer
206 Floating gate conductive layer
207 First groove
208 Second gate dielectric layer
208a Word line dielectric layer
209 Second conductive layer
210 Word line conductive layer
211 Drain region
212 Source region
213 Peripheral doped region
214 Self-aligned silicide layer
215 Contact plug
216 Sidewall structure
217 Inter-layer dielectric layer
218 Bit line
219 Inversion channel

### DETAILED DESCRIPTION OF THE PREFERRED EMBODIMENTS

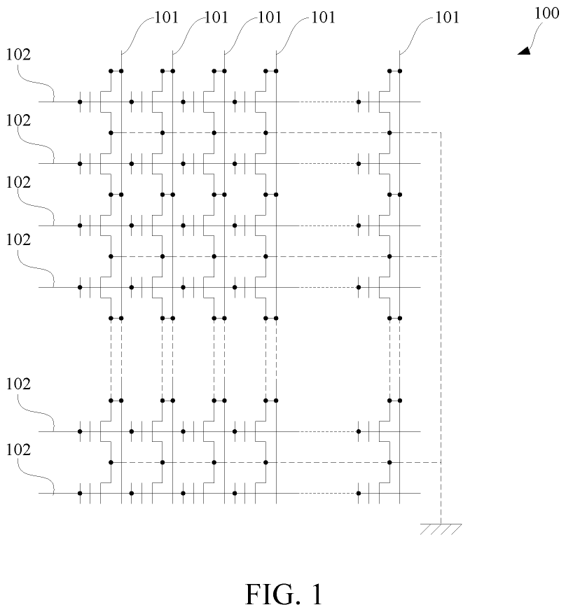

The implementation mode of the present disclosure will be described below through specific embodiments. One skilled in the art can easily understand other advantages and effects of the present disclosure according to contents disclosed by the description. The present disclosure can also be implemented or applied through other different specific implementation modes. Various modifications or changes can also be made to all details in the description based on different points of view and applications without departing from the spirit of the present disclosure. Referring to FIGS. 1 to 30, it needs to be stated that the drawings provided in the following embodiments are just used for schematically describing the basic concept of the present disclosure. Thus, the figures only illustrate components related to the present disclosure and are not drawn according to the numbers, shapes and sizes of components during actual implementation. The configuration, number and scale of each component during actual implementation thereof may be freely changed, and the component layout configuration thereof may be more complex.

This embodiment provides a non-volatile memory. The non-volatile memory includes at least one non-volatile memory cell. Referring to FIG. 1, it is an exemplary circuit diagram of the non-volatile memory. The memory 100 includes at least one bit line 101 and at least one word line 102. During operation, a memory system applies a suitable signal to the bit line and the word line to select a single memory cell. The memory system may read data from the memory cell, program the memory cell, or erase the memory cell.

In an example, at least two non-volatile memory cells shares one drain region, and at least two non-volatile memory cells share one source region.

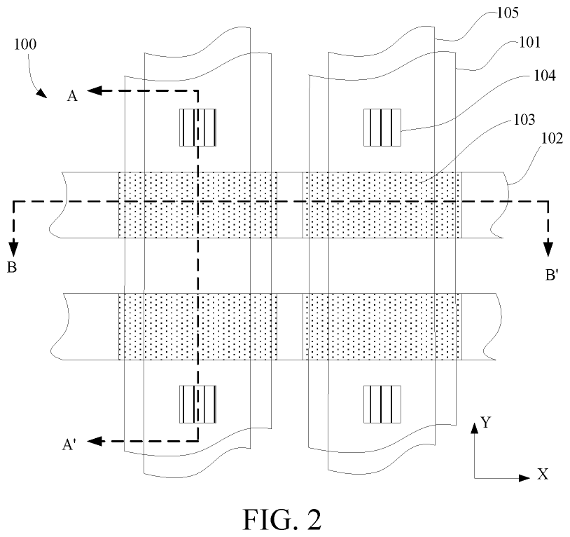

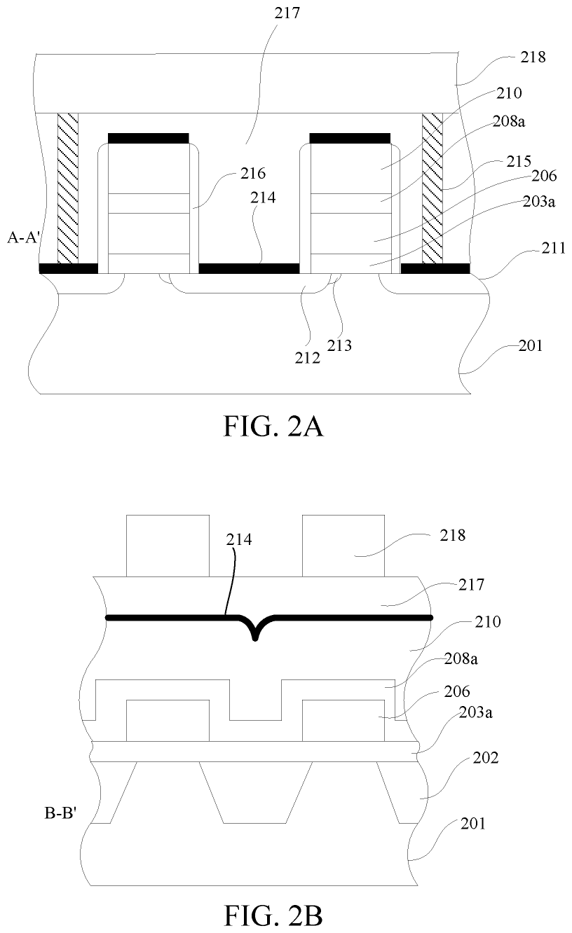

Referring to FIG. 2, it is a plane layout of the non-volatile memory, showing a layout of a bit line 101, a word line 102, a floating gate 103, an active region 105, and a contact region 104 of the memory 100.

Referring to FIG. 2A and FIG. 2B, FIG. 2A is a cross-section diagram taken along line A-A′ in FIG. 2, and FIG. 2B is a cross-section diagram taken along line B-B′ in FIG. 2. The bit line 101 shown in FIG. 2 may be implemented through a bit line 218. The word line 102 shown in FIG. 2 may be implemented through a word line conductive layer 210. The floating gate 103 in FIG. 2 may be implemented through a floating gate conductive layer 206. The active region 105 shown in FIG. 2 may be defined in a substrate 201 through a shallow trench isolation structure 202. The contact region 104 shown in FIG. 2 may be implemented through a contact plug 215.

Referring to FIG. 2, in an example, an X-direction and a Y-direction (first direction) are defined in the present disclosure. The X-direction is consistent with an extending direction of the word line, and the Y-direction is perpendicular to the X-direction.

Referring to FIG. 2A and FIG. 2B, the non-volatile memory cell in the non-volatile memory includes the substrate 201, a floating gate structure, a word line structure, a drain region 211, a source region 212 and a peripheral doped region 213. The floating gate structure is located on the substrate 201 and sequentially includes a floating gate dielectric layer 203a and a floating gate conductive layer 206 from bottom to top. The floating gate dielectric layer 203a is located on the substrate 201. The floating gate conductive layer 206 is located on the floating gate dielectric layer 203a. The floating gate dielectric layer 203a has a thickness ranging from, for example, 7 to 14 nm. The floating gate conductive layer 206 has a thickness ranging from, for example, 8 to 50 nm.

Referring to FIG. 2A, the word line structure is located on the floating gate structure and sequentially comprises a word line dielectric layer 208a and a word line conductive layer 210 from bottom to top. The word line dielectric layer 208a is located on the floating gate conductive layer 206. The word line dielectric layer 208a has a thickness ranging from 3 to 8 nm, and the word line conductive layer 210 has a thickness ranging from 80 to 250 nm.

Referring to FIG. 2A, the drain region 211 is located in the substrate 201. The drain region 211 is adjacent to a first edge of the floating gate structure. The drain region 211 is, for example, an N-type doped drain region.

Referring to FIG. 2A, the source region 212 is located in the substrate 201. The source region 212 is adjacent to a second edge of the floating gate structure. The source region 212 is, for example, a P-type doped source region. A doping type of the source region 212 is different from a doping type of the drain region 211. The floating gate structure is located between the source region 212 and the drain region 211.

Referring to FIG. 2A, the peripheral doped region 213 is located around both sides of the source region 212. The peripheral doped region 213 is adjacent to the second edge of the floating gate structure. The peripheral doped region 213 is located under the floating gate structure. A doping type of the peripheral doped region 213 is different from the doping type of the source region 212. The peripheral doped region 213 is, for example, an N-type doped region.

Referring to FIG. 2A, in an example, the non-volatile memory may further include an inter-layer dielectric layer 217, at least one bit line 218, and at least one contact plug 215. The inter-layer dielectric layer 217 is located on the substrate 201 and covers the floating gate structure and the word line structure. The contact plug 215 is located in the inter-layer dielectric layer 217. A top end of the contact plug 215 is connected to the bit line 218, and a bottom end of the contact plug 215 is connected to the drain region 213.

Referring to FIG. 2A, in an example, the non-volatile memory may further include self-aligned silicide layers 214 and sidewall structures 216. The self-aligned silicide layers 214 are located on the drain region 211, the source region 212, and the word line conductive layer 210. The sidewall structures 216 are located at both sides of the floating gate structure and the word line structure.

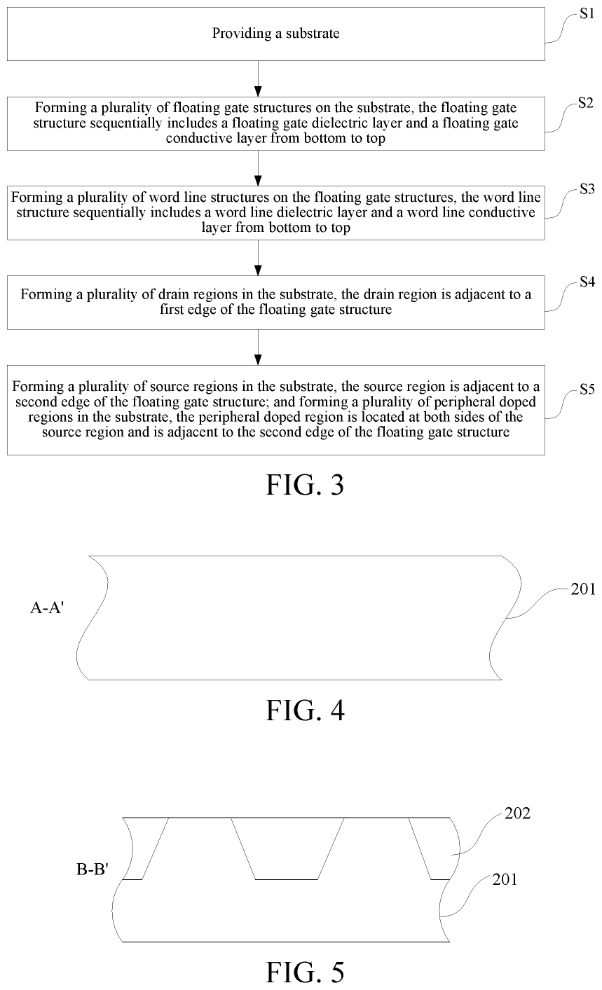

Referring to FIG. 3, this embodiment further provides a manufacturing method for a non-volatile memory. In an example, referring to FIGS. 4 to 27, these are schematic diagrams of cross-section structures presented in steps of the manufacturing method for a non-volatile memory. For the structures presented in the steps, cross sections taken along the A-A′ direction and B-B′ direction are shown.

In FIG. 4 and FIG. 5, cross-section diagrams of the provided substrate 201 are shown. A shallow trench isolation structure 202 may be formed in the substrate 201, so as to define a plurality of active regions in the substrate 201.

In FIG. 4 and FIG. 5, in an example, the substrate 201 may be a P-type doped semiconductor substrate, such as a P-type silicon substrate. In other embodiments, the substrate 201 may also be an N-type doped semiconductor substrate. In this case, all N-type doped regions in the subsequent description need to be replaced with P-type doped regions. In another embodiment, a simple P-type substrate may be replaced with a triple-well structure. For example, a P-type substrate includes a deep N-well, and a P-well is formed in the N-well.

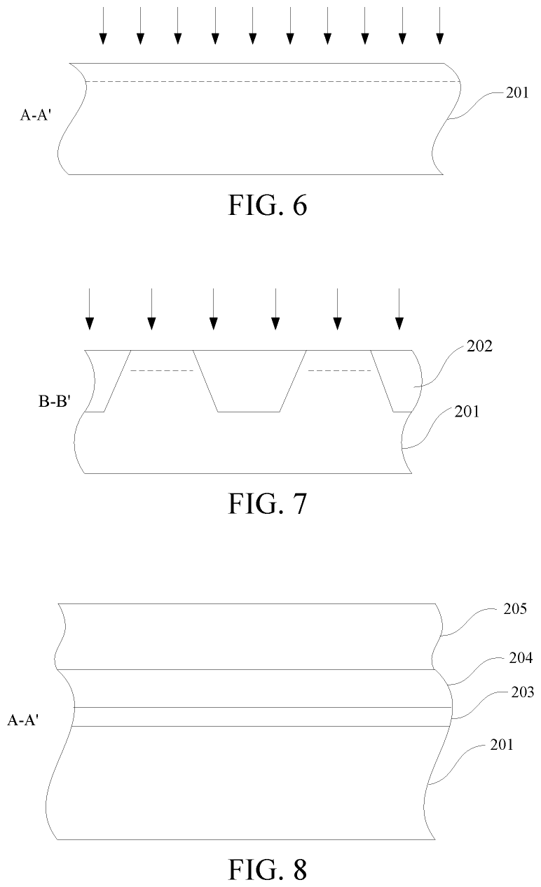

In FIG. 6 and FIG. 7, a patterned photoresist layer is first formed to cover a peripheral region and expose an array region (not shown in the figure). Then, for example, boron ions or boron fluoride ions (BF₂) are implanted to adjust a threshold. Next, implantation damage is repaired by using a rapid thermal annealing process, and the implanted dopant is activated. In FIG. 6 and FIG. 7, an implantation point for threshold adjustment is indicated by using dashed lines, and an implantation direction of the boron ions or boron fluoride ions is indicated by using arrows. In this embodiment, the implantation direction is preferably a vertical direction. In other embodiments, tilted implantation may be performed. In this embodiment, an ion implantation dosage ranges from, for example, 10¹²/cm² to 8*10¹³/cm².

It should be noted that, in the technical solution of the present disclosure, threshold adjustment through ion implantation is not mandatory, and this step may be omitted in other embodiments.

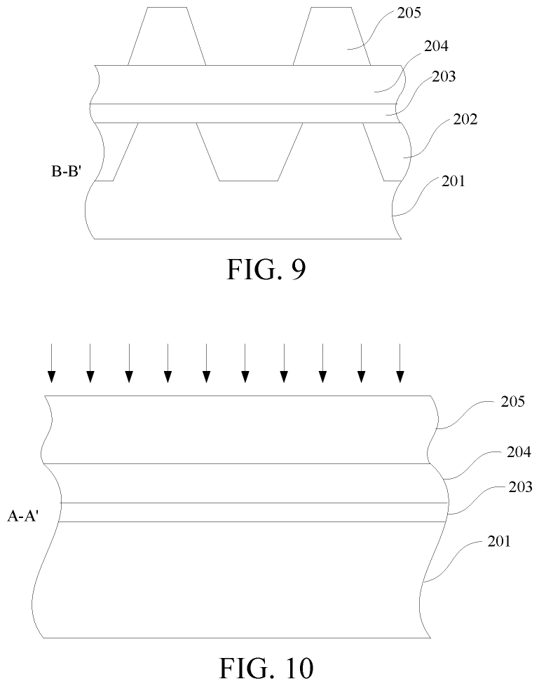

In FIG. 8 and FIG. 9, a first gate dielectric layer 203 is first formed on the substrate 201. A material of the first gate dielectric layer 203 may include, for example, an oxide or a nitrogen oxide. A method of forming the first gate dielectric layer 203 may be, for example, thermal growth. The first gate dielectric layer 203 has a thickness ranging from, for example, 7 to 14 nm. Then, a first conductive layer 204 is formed on the first gate dielectric layer 203. A material of the first conductive layer 204 may include, for example, P-type or N-type polysilicon. The first conductive layer 204 has a thickness ranging from, for example, 8 to 50 nm. Finally, a patterned photoresist layer 205 is formed on the first conductive layer 204, so as to define a floating gate conductive layer 206 in the first direction (Y-direction).

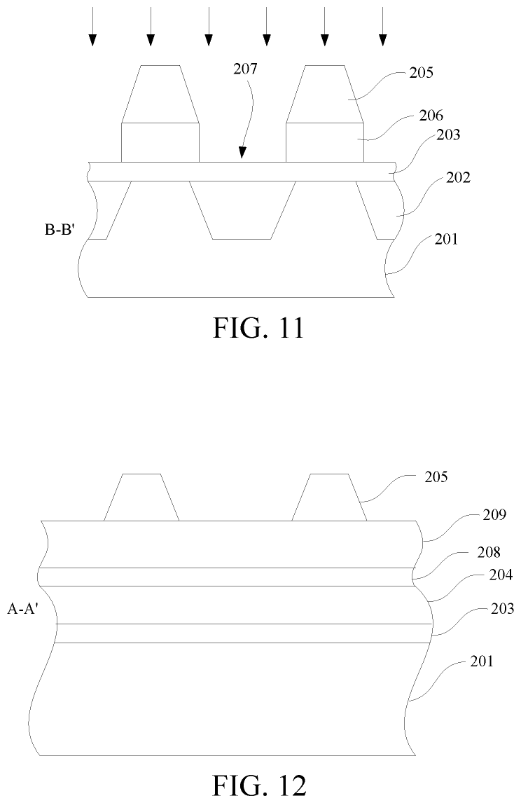

In FIG. 10 and FIG. 11, a plurality of first grooves 207 extending along the first direction is formed in the first conductive layer 204 to divide the first conductive layer 204 into a plurality of the floating gate conductive layers 206 extending along the first direction.

In FIG. 10 and FIG. 11, in an example, the floating gate conductive layers 206 are formed by using anisotropic etching in combination with a certain degree of isotropic etching. The isotropic etching helps thoroughly remove the first conductive layer 204 located in the first grooves. In other embodiments, anisotropic etching may be used, and etching process parameters are controlled to obtain high etching selectivity of polysilicon over an oxide, so as to ensure that the first gate dielectric layer 203 in the first grooves is not excessively etched while the first conductive layer in the first grooves is thoroughly removed.

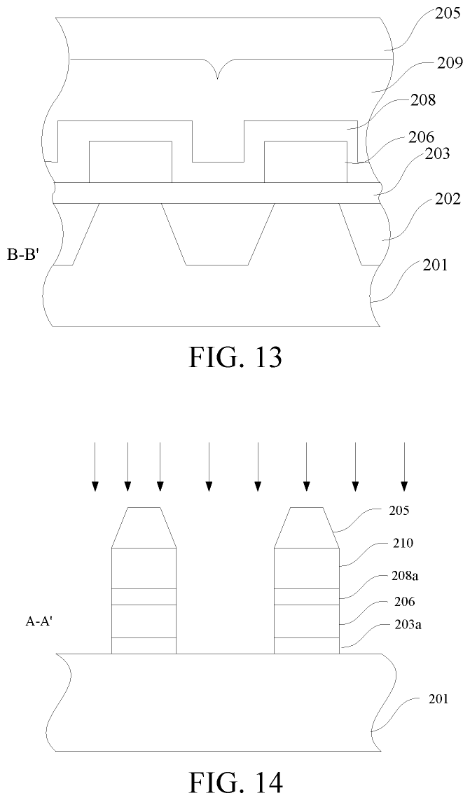

In FIG. 12 and FIG. 13, the patterned photoresist layer 205 is first removed. Then, a second gate dielectric layer 208 is formed on the surface of the floating gate conductive layer 206 and a partial surface, which is exposed by the first groove 207, of the first gate dielectric layer 203, and a second conductive layer 209 is formed on the surface of the second gate dielectric layer 208. Finally, a patterned photoresist layer 205 is formed on the second conductive layer 209, to define a word line conductive layer 210.

In FIG. 12 and FIG. 13, in an example, a material of the second gate dielectric layer 208 includes either of an oxide (such as silicon oxide) and a nitride (such as silicon nitride), or the second gate dielectric layer 208 sequentially includes a first oxide layer (such as silicon oxide), a nitride layer (such as silicon nitride) and a second oxide layer (such as silicon oxide) from bottom to top. The first oxide layer has a thickness ranging from, for example, 3 nm to 7 nm. The nitride layer has a thickness ranging from, for example, 4 nm to 8 nm. The second oxide layer has a thickness ranging from, for example, 3 nm to 7 nm. A material of the second conductive layer 209 includes, but is not limited to, N-type polysilicon. The second conductive layer 209 has a thickness ranging from, for example, 80 nm to 250 nm.

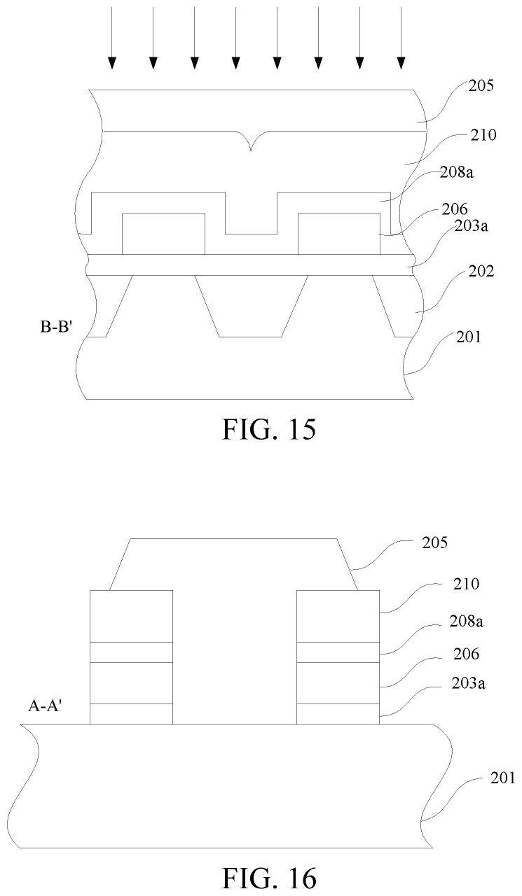

In FIG. 14 and FIG. 15, the second conductive layer 209, the second gate dielectric layer 208, the first conductive layer 206, and the first gate dielectric layer 203 are etched, to obtain the word line conductive layer 210.

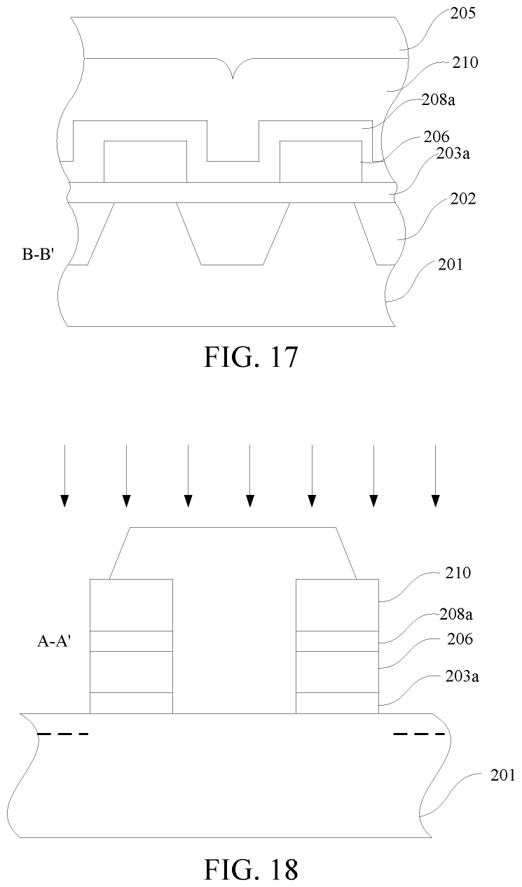

In FIG. 16 and FIG. 17, the patterned photoresist layer 205 is removed first, and then another patterned photoresist layer 205 is formed in the first groove 207 and on the word line conductive layer 210, to expose a part of the substrate 201.

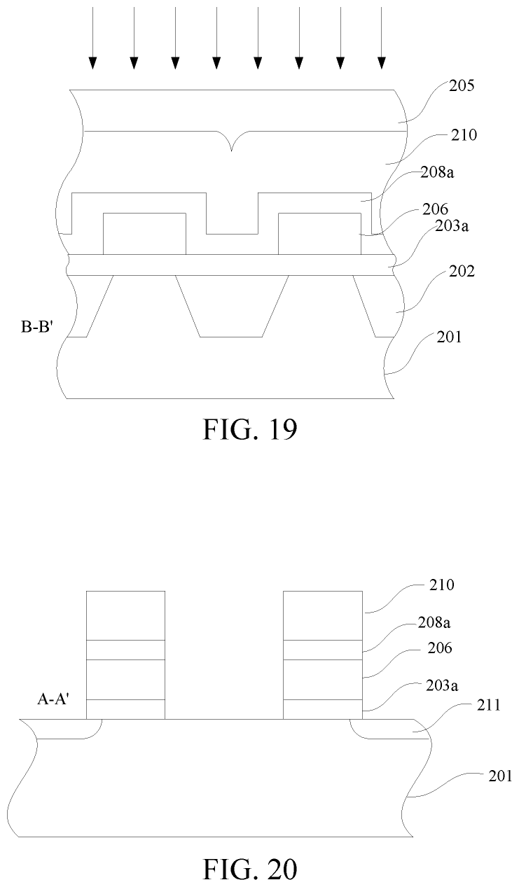

In FIG. 18 and FIG. 19, first-type doping is performed on the exposed part of the substrate 201, to form a drain region 211. The drain region 211 is adjacent to a first edge of the floating gate structure. In this embodiment, the implantation direction is optionally a vertical direction. In other embodiments, tilted implantation may be performed. In this embodiment, an ion implantation dosage ranges from, for example, 10¹⁵/cm² to 10¹⁶/cm², and doping energy is, for example, 20 to 80 KeV.

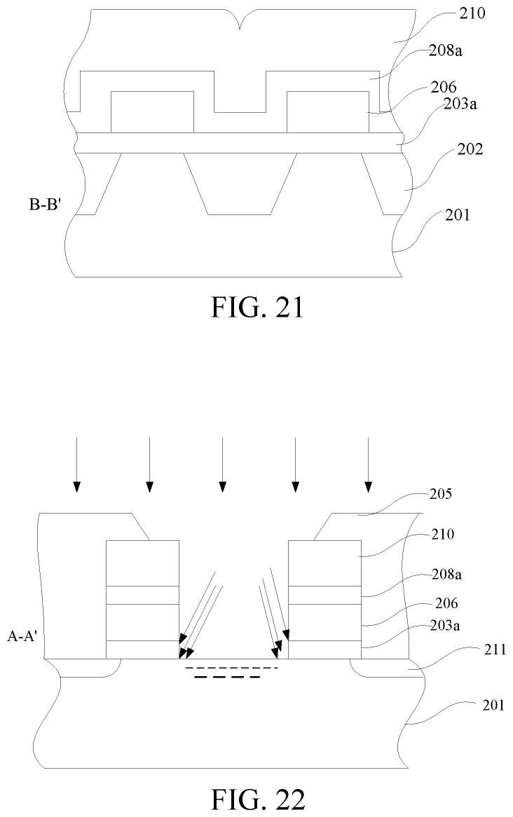

In FIG. 20 and FIG. 21, the patterned photoresist layer 205 is removed first, then implantation damage is repaired by using a rapid thermal annealing process, and the implanted dopant is activated.

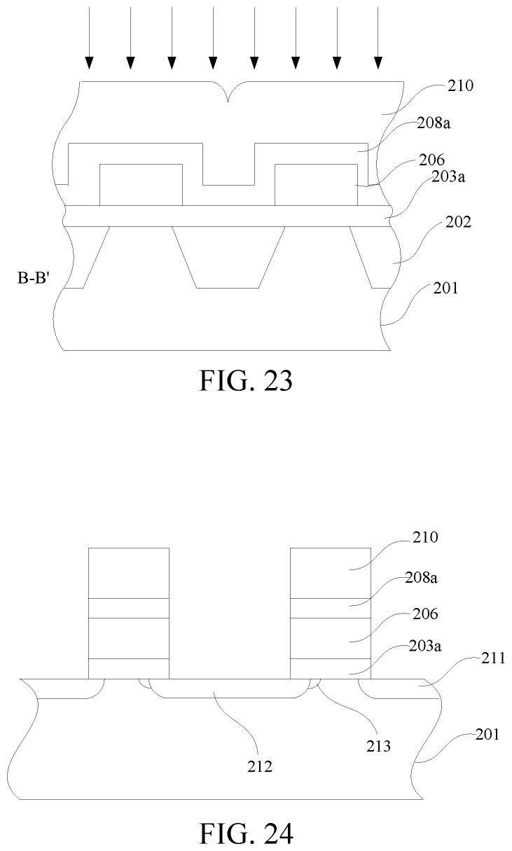

In FIG. 22 and FIG. 23, a patterned photoresist layer 205 is first formed on the substrate. The patterned photoresist layer 205 covers the drain region 211 and exposes a part of the substrate 201. Then, second-type doping is performed on the substrate 201 to form a source region 212. The source region 212 is adjacent to a second edge of the floating gate structure. In this embodiment, the implantation direction is optionally a vertical direction. In other embodiments, tilted implantation may be performed. In this embodiment, an ion implantation dosage ranges from, for example, 2*10¹⁵/cm² to 10¹⁶/cm², and implantation energy is, for example, 10 to 40 KeV. Finally, first-type doping is performed on the exposed part of the substrate 201, to form a peripheral doped region 213. The peripheral doped region 213 is located around both sides of the source region 212 and is adjacent to the second edge of the floating gate structure. A doping type of the peripheral doped region 213 is different from that of the source region 212. A thickness of the peripheral doped region 213 is less than that of the source region 212. The peripheral doped region 213 is located under the floating gate structure. In this embodiment, the implantation direction is optionally a tilted direction. A tilt angle is, for example, between 25° and 60°; an ion implantation dosage ranges from, for example, 10¹⁴/cm²-10¹⁵/cm²; and implantation energy is, for example, 10 to 30 KeV. Doping is performed through two channels.

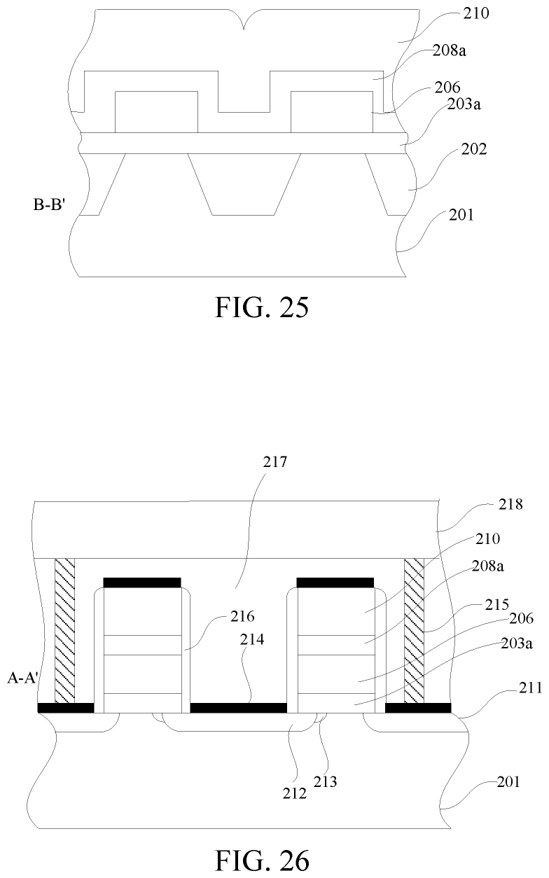

In FIG. 24 and FIG. 25, the patterned photoresist layer 205 is removed first, then implantation damage is repaired by using a rapid thermal annealing process, and the implanted dopant is activated, to form the source region 212 and the peripheral doped region 213.

In FIG. 26 and FIG. 27, a back end of line interconnection structure is formed, including forming an inter-layer dielectric layer 217 on the substrate 201, forming at least one contact hole in the inter-layer dielectric layer 217, forming at least one contact plug 215 in the inter-layer dielectric layer 217, and forming at least one bit line 218 on the inter-layer dielectric layer 217. The inter-layer dielectric layer 217 covers the floating gate structure and the word line structure. A bottom end of the contact plug 215 is connected to the drain region 211. The bit line 218 is connected to a top end of the contact plug 215. A conductive metal may be used as a material of the bit line 218.

In FIG. 26 and FIG. 27, self-aligned silicide layers 214 and sidewall structures 216 are further formed. The self-aligned silicide layers 214 are located on the substrate 201 and the word line conductive layer 210. The sidewall structures 216 are located on both sides of the word line structure and the floating gate structure. The height of the sidewall structures 216 is lower than or equal to or not higher than the height of the word line structure 210.

In conclusion, in this embodiment, the floating gate structure and the word line structure are formed first. Then, the drain region, the source region, and the peripheral doped region are formed. The self-aligned process effectively improves the precision and effectively controls the size of the memory.

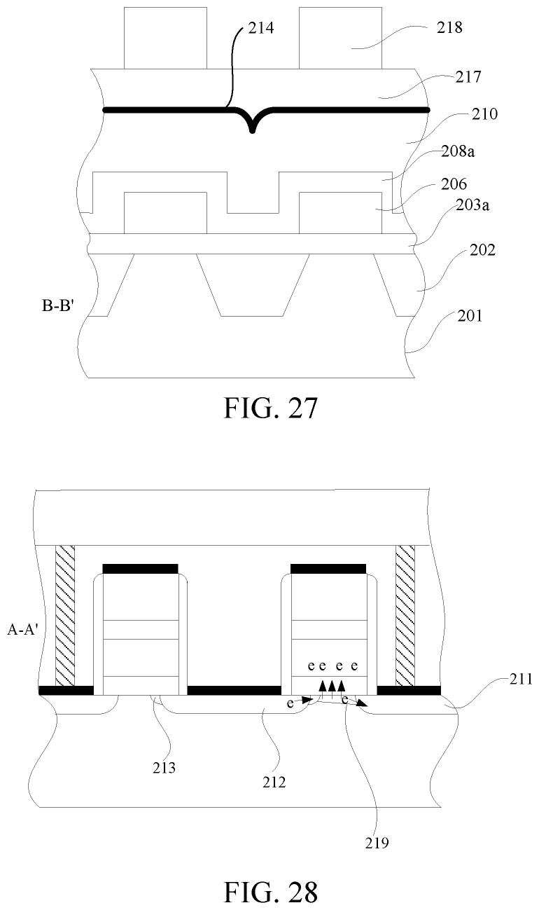

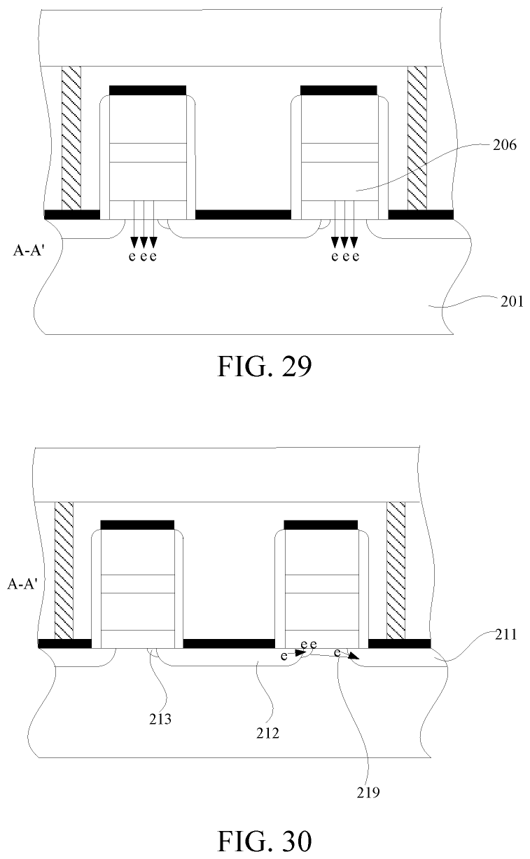

Hereinafter, a programming operation, an erasing operation, and a reading operation of a non-volatile memory consistent with the present disclosure are illustrated by using the non-volatile memory in FIG. 26. And FIG. 28 is a schematic diagram of programming operation of a non-volatile memory of the present disclosure, FIG. 29 is a schematic diagram of erasing operation of a non-volatile memory of the present disclosure, and FIG. 30 is a schematic diagram of reading operation of a non-volatile memory of the present disclosure.

Referring to FIG. 26 and FIG. 28, during a programming operation, a voltage is applied on the word line conductive layer 210, and an inversion channel 219, such as an N-type inversion channel, may be formed under the floating gate structure. The inversion channel 219 connects the drain region 211 and the N-type doped region 213. The N-type inversion channel 219 brings a voltage of the drain region 211 to the peripheral doped region 213, and then a band-to-band tunnelling results between the source region 212 and the peripheral doped region 213. Under the effect of a strong vertical electric field, some of the band-to-band tunnelling electrons are directly injected into the floating gate conductive layer 206, and some of the tunnelling electrons produce impact ionization to form electron-hole pairs, from which some of the electrons are injected into the floating gate conductive layer 206; the holes are swept to the substrate 201 or the source region 212; some of the band-to-band tunneling electrons flow into the inversion channel 219 and then enter the floating gate conductive layer 206 by tunneling effect, and the rest of the electrons continue to flow to the drain region 211 to create hot electrons that can be also injected into the floating gate conductive layer 206. The voltage of the source region 212 is, for example, (−3)-0 V, and the voltage of the drain region 211 is, for example, 1.5-3.6 V, and the voltage of the word line conductive layer 210 is, for example, 8-14 V.

Referring to FIG. 26 and FIG. 29, during an erasing operation, a voltage is applied on the word line conductive layer 210, and electrons in the floating gate conductive layer 206 enter the substrate 201, or the source region 212, or the drain region 213 by a tunneling effect. The voltage of the source region 212 and the drain region 211 is 0 V, and the voltage of the word line conductive layer 210 is, for example, −8 to −15 V.

Referring to FIG. 26 and FIG. 30, during reading operations, a voltage is applied on the word line conductive layer 210. If a cell is already erased, an inversion channel 219, such as an N-type inversion channel, may be formed under the floating gate structure. The drain region 211 and the peripheral doped region 213 are connected through the inversion channel 219. The word line voltage causes electrons to accumulate on the upper surface of the peripheral doped region 213. Therefore, a band-to-band tunnelling results between the source region 212 and the peripheral doped region 213 to generate a high cell current. In addition, if a cell is already programmed, there is no cell current, because no inversion channel is formed due to electrons stored in floating gate conductive layer 206. The voltage of the word line conductive layer 210 is, for example, 1.2 to 3.6 V.

In this embodiment, when reading operations are performed on the memory, the peripheral doped region is connected to the drain region through an inversion channel while electrons are accumulated on the upper surface of the peripheral doped region, so that a reading voltage is effectively reduced, thereby simplifying the circuit design of the memory.

In conclusion, the present disclosure provides a non-volatile memory and a manufacturing method for the same. A peripheral doped region is formed on a substrate; during reading operations, positive word line voltage, instead of negative voltage as in the prior art, is required to form the inversion channel between the peripheral doped region and a drain region, and the accumulated electrons on the upper surface of the peripheral doped region, so that a same polarity voltage is achieved with a lower power supply voltage, thereby simplifying the circuit design of the memory. The non-volatile memory provided in the present disclosure has a simple structure, a small size, and a highly operable manufacturing process. Therefore, the present disclosure effectively overcomes various disadvantages in the prior art and achieves high industrial application value.

The term “one embodiment,” “an embodiment” or “a specific embodiment” mentioned in the whole specification means that a particular feature, structure or characteristic described in combination with the embodiment is included in at least one embodiment of the present disclosure and not necessarily included in all embodiments. Therefore, various representations of the phrase “in one embodiment,” “in an embodiment” or “in a specific embodiment” at different places throughout the whole specification do not necessarily refer to the same embodiment. In addition, particular features, structures or characteristics of any specific embodiment of the present disclosure may be combined with one or more other embodiments in any suitable manner. It should be understood that, other variations and modifications of the embodiments of the present disclosure described and illustrated herein are possible in light of the teachings herein and are considered as a part of the spirit and scope of the present disclosure.

It should be further understood that one or more of the elements depicted in the drawings may be implemented in a more separated or integrated manner, or even removed as being inoperable in some cases, or provided as being useful according to a particular application.

In addition, any mark arrow in the drawings should be considered only as exemplary and not limiting, unless otherwise indicated explicitly. In addition, the term “or” used herein is generally intended to mean “and/or” unless otherwise indicated. Combinations of components or steps will also be considered as being indicated, where terminology is foreseen as rendering the ability to separate or combine is unclear.

As used in the description herein and throughout the claims that follow, “a”, “an”, and “the” comprise plural references unless the context clearly indicates otherwise. Also, as used in the description herein and throughout the claims that follow, the meaning of “in” comprises “in” and “on” unless the context clearly indicates otherwise.

The foregoing description of the illustrated embodiments of the present disclosure (including what is described in the abstract) is not intended to be exhaustive or to limit the present disclosure to the precise forms disclosed herein. While specific embodiments of the present disclosure and examples of the present disclosure are described herein for illustrative purposes only, various equivalent modifications are possible within the spirit and scope of the present disclosure, as a person skilled in the art will recognize and appreciate. As indicated, these modifications may be made to the present disclosure in light of the foregoing description of the illustrated embodiments of the present disclosure, and the modifications are comprised within the spirit and scope of the present disclosure.

The system and method are generally described herein as details that facilitate understanding of the present disclosure. In addition, numerous specific details are provided to provide a thorough understanding of the embodiments of the present disclosure. A person skilled in the art will recognize, however, that an embodiment of the present disclosure can be practiced without one or more of the specific details, or by using other apparatuses, systems, assemblies, methods, components, materials, parts, or the like. In other instances, well-known structures, materials, and/or operations are not specifically shown or described in detail to avoid obscuring aspects of the embodiments of the present disclosure.

Thus, while the present disclosure has been described herein with reference to the specific embodiments thereof, a latitude of modifications, various changes and substitutions are intended in the foregoing disclosure, and it will be appreciated that in some instances, some features of the embodiments of the present disclosure will be employed without a corresponding use of other features without departing from the scope and spirit of the present disclosure as set forth. Therefore, many modifications may be made to adapt a particular situation or material to the essential scope and spirit of the present disclosure. The present disclosure is not intended to be limited to the particular terms used in the following claims and/or to the particular embodiment disclosed as the best mode contemplated for carrying out the present disclosure. The present disclosure will comprise any and all embodiments and equivalents falling within the scope of the appended claims. Thus, the scope of the present disclosure is to be determined solely by the appended claims.

What is claimed is:

1. A non-volatile memory, comprising:
a substrate;
at least one floating gate structure located on the substrate, wherein the floating gate structure sequentially comprises a floating gate dielectric layer and a floating gate conductive layer;
at least one word line structure located on the floating gate structure, wherein the word line structure sequentially comprises a word line dielectric layer and a word line conductive layer;
at least one drain region located in the substrate, wherein the drain region is adjacent to a first edge of the floating gate structure;
at least one source region located in the substrate, wherein the source region is adjacent to a second edge of the floating gate structure; and
at least one peripheral doped region located in the substrate, wherein the peripheral doped region is formed around both sides of the source region and is adjacent to the second edge of the floating gate structure, and a doping type of the peripheral doped region is different from a doping type of the source region.

2. The non-volatile memory as in claim 1, wherein the doping type of the peripheral doped region is the same as a doping type of the drain region.

3. The non-volatile memory as in claim 1, wherein a thickness of the peripheral doped region is less than a thickness of the source region.

4. The non-volatile memory as in claim 1, wherein the peripheral doped region is located under the floating gate structure.

5. The non-volatile memory as in claim 1, wherein when a voltage is applied on the word line structure, an inversion channel is formed under the floating gate structure, wherein the drain region and the peripheral doped region are connected through the inversion channel.

6. The non-volatile memory as in claim 1, further comprising self-aligned silicide layers and sidewall structures, wherein the self-aligned silicide layers are located on the drain region, the source region and the word line conductive layer, and the sidewall structures are located at both sides of the floating gate structure and the word line structure.

7. A manufacturing method for a non-volatile memory, comprising:
providing a substrate;
forming at least one floating gate structure on the substrate, wherein the floating gate structure sequentially comprises a floating gate dielectric layer and a floating gate conductive layer;
forming at least one word line structure on the floating gate structure, wherein the word line structure sequentially comprises a word line dielectric layer and a word line conductive layer;
forming at least one drain region in the substrate, wherein the drain region is adjacent to a first edge of the floating gate structure;
forming at least one source region in the substrate, wherein the source region is adjacent to a second edge of the floating gate structure; and
forming at least one peripheral doped region in the substrate, wherein the peripheral doped region is formed around both sides of the source region and is adjacent to the second edge of the floating gate structure, and a doping type of the peripheral doped region is different from a doping type of the source region.

8. The manufacturing method as in claim 7, wherein forming the floating gate structure comprises:
forming a first gate dielectric layer on the substrate;
forming a first conductive layer on the first gate dielectric layer; and
removing a part of the first gate dielectric layer and a part of the first conductive layer, to form the floating gate structure extending along a first direction.

9. The manufacturing method as in claim 7, wherein forming the word line structure comprises:
forming a second gate dielectric layer on the floating gate structure and the exposed first gate dielectric layer; and
forming a second conductive layer on the second gate dielectric layer, and removing a part of the second conductive layer and a part of the second gate dielectric layer to form the word line structure.

10. The manufacturing method as in claim 7, wherein forming the drain region comprises:
forming a patterned photoresist layer on the word line structure to expose a part of the substrate; and
performing first-type doping on the exposed part of the substrate to form the drain region.

11. The manufacturing method as in claim 7, wherein forming the source region and the peripheral doped region comprises:
forming a patterned photoresist layer on the substrate, wherein the patterned photoresist layer covers the drain region to expose a part of the substrate;
performing second-type doping on the exposed part of the substrate to form the source region; and
performing first-type doping on the exposed part of the substrate to form the peripheral doped region.

12. The manufacturing method as in claim 7, wherein during forming of the peripheral doped region, doping energy ranges from 10 to 30 KeV, and an ion implantation dosage ranges from 10¹⁴/cm² to 10¹⁵/cm².

13. The manufacturing method as in claim 7, further comprising:
forming an inter-layer dielectric layer on the substrate, wherein the inter-layer dielectric layer covers the floating gate structure and the word line structure;
forming at least one contact plug in the inter-layer dielectric layer, wherein a bottom end of the contact plug is connected to the drain region; and
forming at least one bit line on the inter-layer dielectric layer, wherein the bit line is connected to a top end of the contact plug.
